(19) United States
(12) Patent Application Publication
(10) Pub. No.: US 2008/0191197 A1
(43) Pub. Date: Aug. 14, 2008

(54) Semiconductor Arrangement Having a Resistive Memory

(75) Inventors: Andreas Walter, Dresden (DE); Recai Sezi, Roettenbach (DE); Reimund Engl, Regensburg (DE); Anna Maltenberger, Leutenbach (DE); Joerg Schumann, Dresden (DE); Thomas Weitz, Bad Duerkheim (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/572,951

(22) PCT Filed: Jul. 21, 2005
(86) PCT No.: PCT/EP05/53546

§ 371 Date: Jan. 30, 2008

(30) Foreign Application Priority Data
Jul. 30, 2004 (DE) 10 2004 037 149.0

(51) Int. Cl. H01L 51/30; H01L 51/40

(52) U.S. Cl. 257/40; 438/99; 257/E51.025

(57) ABSTRACT

A memory cell reversibly switchable between different stable electrical resistance states, the memory cell having a first electrode and a second electrode and an active layer arranged between the first and the second electrode, the active layer including a compound represented by general formula

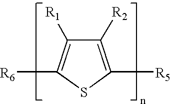

, wherein R₁ and R₂ are independently selected from —H, —(CH₂)ₘCH₃, -phenyl, —O—(CH₂)ₘCH₃, —O-phenyl, —S(CH₂)ₘCH₃, —S-aryl, —NR₃R₄, —SR₃ and -halogen; R₁ and R₂ may together form a ring; R₅ and R₆ are independently selected from —H, -alkyl, -aryl and -heteroaryl; m is either 0 or an integer ranging from 1 to 10; n is an integer ranging from 2 to 1000; and a compound represented by general formula

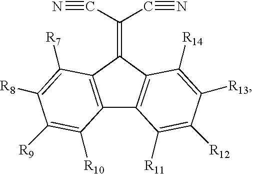

wherein R₇, R₈, R₉, R₁₀, R₁₁, R₁₂, R₁₃, and R₁₄ are independently selected from the group consisting of —H, —(CH₂)ₘCH₃, -phenyl, —O—(CH₂)ₘCH₃, —O-phenyl, —CO(CH₂)ₘCH₃, -halogen, —CN and —NO₂; R₇ and R₈ may together form a ring; R₈ and R₉ may together form a ring; R₉ and R₁₀ may together form a ring; R₁₁ and R₁₂ may together form a ring; R₁₂ and R₁₃ may together form a ring; and R₁₃ and R₁₄ may together form a ring.

Furthermore, a process for the production of the cells according to the invention is provided, as well as the novel use of a composition which can be used as active material for the memory cells.

The invention relates to a semiconductor arrangement comprising a resistive memory.

One of the substantial efforts in the further development of modern storage technologies is the increase of the integration density, so that the reduction in the structure sizes of the memory cells on which the memory devices are based is very important.

A plurality of microelectronic elements and in particular memory cells which have a size of a few nanometres has been described in recent years. A concept for designing such memory cells is to arrange, between two electrodes, an active layer which can reversibly change certain properties, such as, for example, ferromagnetic properties or electrical resistance, depending on the voltage. Depending on the applied voltage, the cell can be switched between two states, so that one state can be assigned, for example, to the information state “0” and the other state can be assigned to the information state “1”.

Various memory cells having an active layer have been described in the prior art.

Compared with the cells which have a ferroelectric material between two electrodes, the cell which has, between two electrodes, an active layer which can change the electrical resistance depending on the applied voltage has the advantage that it has a substantially higher signal ratio between the OFF and ON state and need not be rewritten after the read process, since the reading of the state is not destructive.

Bandyopadhyay et al.: Applied Physics Letters, Vol. 82, pages 1215-1217 “Large conductance switching memory effects in organic molecules for data-storage applications” describe an active layer arranged between two electrodes and consisting of rose Bengal (4,5,6,7-tetrachloro-2′,4′,5′,7′-tetraiodofluorescein) with a polyallylamine hydrochloride polymer. The electrode consists of indium tin oxide on glass. The production of the active layer is, however, very inconvenient and requires treatment in an oven for several hours in vacuo. In addition, the active layer is limited to the indium tin oxide electrode.

A further memory cell comprising an active material which exhibits switchable behaviour is described in Yang et al.: Applied Physics Letters, Vol. 80, 2002, pages 2997-2999 “Organic Electrical Bistable Devices and Rewritable Memory Cells”. The active material consists of 2-amino-4,5-imidazoledicarbonitrile (AIDCN). The memory cell according to this prior art consists of a plurality of layers which have the following composition: an aluminium alloy deposited on glass, an AIDCN layer arranged thereon, a metal layer, a further AIDCN layer and a cathode. For switchability, this system requires the five layers described above, which makes the production very complex. A further disadvantage of the cells according to this prior art is that the cells can be switched only with aluminium electrodes and that the active layer can be applied only by means of vacuum vapour deposition.

The object of the present invention is to propose further memory cells comprising an active layer (memory layer) arranged between two electrodes, the memory cells permitting a high integration density, being capable of being switched between two stable states of different electrical resistance, being easy to process by conventional methods in microelectronics and allowing the use of the electrodes customary in microelectronics.

A further object of the invention is to propose novel active materials which can be used as an active layer in the memory cells.

The object of the invention is achieved by a memory cell comprising two electrodes and an active layer arranged in between, the active layer comprising

(a) a compound of the structure designated in the general formula I:

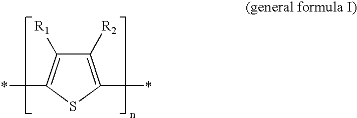

in which
R₁ to R₂, independently of one another, may have the following meaning:
—H, —(CH₂)ₘCH₃, -phenyl, —O—(CH₂)ₘCH₃, —O-phenyl, —S(CH₂)ₘCH₃, —S-aryl, —NR₃R₄, —SR₃ or a halogen atom, it being possible for R₁ and R₂ together to form a ring, and R₃ and R₄, independently of one another, denoting —H, alkyl, preferably having 1-10 C atoms, -aryl, -heteroaryl and m being 0 or an integer in the range of 1-10, and n is an integer in the range of 2 to 1000;
and
(b) a compound of the general formula II:

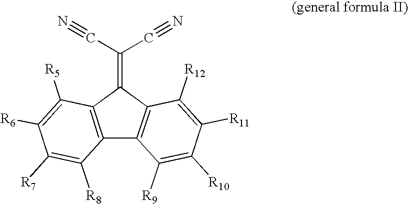

in which R₅ to R₁₂, independently of one another, may have the following meaning: —H, —(CH₂)ₘCH₃, -phenyl, —O—(CH₂)ₘCH₃, —O-phenyl, —CO(CH₂)ₘCH₃, -halogen, —CN and/or —NO₂, it being possible for R₅ and R₆ or R₆ and R₇, R₇ and R₈, R₉ and R₁₀, R₁₀ and R₁₁ and/or R₁₁ and R₁₂ together to form a ring, m having the abovementioned meaning.

However, it is also possible to use more than one compound of the general formula I and one compound of the general formula II.

The terminal groups of the compound a), which have not been shown in the general formula I, may denote —H, aryl or alkyl radicals, optionally with heteroatoms, such as N, O or S. Comonomers of two or more thiophenes which have different R1 and/or R2 are also suitable.

Preferred compounds of group a) are polyalkylthiophenes and polyhexylthiophenes or polythiophene.

The advantages of the cell design according to the invention are a very simple design, reversible, reproducible switchability, a ratio of the ON to OFF resistances of 2-1000 or more, nondestructive reading since there is no necessity of rewriting after reading, nonvolatile information storage, functionality down to film thicknesses of about 20 nm, high thermal stability, switchability in the presence of air and moisture, compatibility with customary electrodes, such as, for example, Cu, Ta, TaN, Al, AlCu, AlSiCu, Ti, TiN, W and customary combinations of these electrodes, suitability of the memory cell for production in a plurality of layers, such as, for example, by the copper damascene technique, etc.

The ratio of the component (a) to (b) can be varied within wide ranges. In a particular embodiment, the ratio of (a) to (b) is in the range from 1:5 to 5:1.

The substrate on which the electrodes have been applied or in which the electrodes are incorporated may be silicon, germanium, gallium arsenide or gallium nitride or any desired material which contains any desired compound of silicon, germanium or gallium. Furthermore, the substrate may also be a polymer, i.e. plastic, which is filled or unfilled or is present as a moulding or film, and may be ceramic, glass or metal. The substrate may also be a preprocessed material and contain one or more layers of contacts, conductor tracks, insulating layers and further microelectronic components.

In a preferred embodiment, the substrate is silicon which has already been processed according to front-end-of-line (FEOL), i.e. already contains electric components, such as transistors, capacitors, etc.—manufactured by the silicon technique. An insulating layer is preferably present between the substrate and the nearest electrode, particularly when the substrate is electrically conductive. However, it is also possible for a plurality of layers to be present between the substrate and the nearest electrode.

The substrate may serve as carrier material or may perform an electrical function (evaluation, control). For the last-mentioned case, there are electrical contacts between the substrate and the electrodes which are applied to the substrate. These electrical contacts are, for example, contact holes (vias) filled with an electrical conductor. However, it is possible for the contacts to be effected from the lower into the upper layers by metallization in the edge regions of the substrate or of the chips.

As already ascertained above, the active layer according to the invention is compatible with a multiplicity of electrodes conventionally used in microelectronics. Electrodes preferably consist of Cu, Al, AlCu, AlSiCu, Ti, TiN, Ta, TaN, W, TiW, TaW, WN, WCN and customary combinations of these electrodes. Furthermore, thin layers of silicon, titanium silicon nitride, silicon oxynitride, silicon oxide, silicon carbide, silicon nitride or silicon carbonitride may also be present in combination with the abovementioned layers or materials.

The abbreviations, such as, for example, TiN, do not reproduce an exact stoichiometric ratio since the ratio of the components can be changed as desired within possible limits.

Various methods are suitable for depositing the abovementioned electrode layers. These may be, for example, PVD, CVD, PECVD, vapour deposition, electroplating, electroless plating or atomic layer deposition (ALCVD).

However, the methods are not limited to these and it is in principle possible to use all methods used in microelectronics for the production of electrodes.

The deposition of the electrode can be effected from the gas phase or from solution.

The electrodes can be structured by means of various customary techniques. The structuring can be effected, for example, by means of hole masks, printing techniques or lithography. In particular, screen printing, microcontact printing and nanoimprinting are particularly preferred as printing techniques.

However, the electrodes can also be structured, for example, by means of the so-called damascene technique. For this purpose, for example, an insulating layer (preferably of silicon oxide) present above the substrate is structured by lithography and etching. After stripping of the photoresist, the electrode layer is deposited so that the trenches or holes in the insulating layer which are formed during the structuring are completely filled with the electrode materials. A part of these materials which projects above the surface of the insulating layer is then ground back. The grinding process can be effected by means of the so-called CMP technique (chemical mechanical planarization). This results in, for example, conductor tracks and/or contact holes which are filled with the electrode materials and embedded in the insulating layer so that they have the same height as the insulating layer.

After the active material is deposited onto the electrode, the top electrode can be produced in exactly the same way as the bottom one. In a preferred embodiment of the invention, the upper conductor tracks are arranged transversely to the lower conductor tracks. Thus, a so-called crosspoint cell, which consists of three layers, namely bottom electrode, active material and top electrode, forms at each point of intersection of the top electrode with the bottom electrode.

The lateral geometry of the cell is not limited to the abovementioned crosspoint arrangement; since, however, the crosspoint arrangement permits a very high integration density, it is preferred for the present invention.

The above-described sandwich structures of the memory cells, consisting of two electrodes and the layer present in between and comprising the active material, can be applied to the substrate not just once but several times in a form stacked one on top of the other. This results in a plurality of planes for the memory cells, each plane consisting of two electrodes and the layer present in between and comprising the active material. It is of course also possible for a plurality of cells to be in a plane (cell array). The various planes can be separated from one another by an insulator, or it is also possible to use not four but three electrodes for two planes located one on top of the other, since it (middle electrode) can serve as the top electrode for the lower plane and as the bottom electrode for the upper plane.

The active material can be applied to the electrode by means of spin coating, for example, by preparation of a solution which contains the components (a) and (b). Suitable solvents are, for example, N-methylpyrrolidone, γ-butyrolactone, methoxypropyl acetate, ethoxyethyl acetate, cyclohexanone, cyclopentanone, ethers of ethylene glycol, such as diethylene glycol diethyl ether, furthermore ethoxyethyl propionate, ethyl lactate, chlorobenzene, dichlorobenzene, chloroform or methylene chloride. A mixture of the abovementioned solvents with optionally further solvents can also be used as the solvent. The formulation may also contain additives, such as, for example, adhesion promoters (for example silanes). The active material can, however, also be applied by means of vacuum vapour deposition. For this purpose, the components (a) and (b) are deposited simultaneously on the electrode (co-evaporation) or the components are applied directly in succession and thus form the active layer.

After spin coating or vacuum vapour deposition, a heating step is effected in each case, for example on a hotplate or the substrate is treated in an oven, in order to dry the film or optionally to complete the reaction, particularly when the components (a) and (b) are deposited on the electrode by means of vacuum vapour deposition. In the case of vacuum vapour deposition, the thermal treatment can, however, also be carried out in a vacuum chamber or even omitted.

The thickness of the layer which contains the active material is in the range of, preferably, from between 20 and 2000 nm, the range between 20 and 200 nm being particularly preferred.

The advantages of the cell according to the invention are that the design of the cell is very simple so that the production can be effected economically. Only two electrodes and an active layer arranged in between are necessary for the cell according to the invention. The cell has a reversible, reproducible switchability under various conditions, such as, for example, in the presence of air and moisture and in a wide temperature range.

The active layer can be applied by means of line-compatible techniques such as spin coating or vapour deposition, without special techniques being necessary for this.

The adhesion of the layer to the electrodes is outstanding and the ratio of the state with low resistance to the state of higher resistance is higher than 2-1000.

The production can be effected by means of customary lithograph processes since the active layer is compatible with a multiplicity of processes.

A particular advantage of the present cell is that the active layer is compatible with customary electrodes. The active layer is switchable with the electrodes and electrode combinations which are used in microelectronics, and the fact that the switchability is very reliable particularly with copper should be emphasized. This is important because copper has the lowest electrical resistance compared with the other electrical conductors which are used as standard in electronics. The production of the cell according to the invention is explained in more detail with reference to examples.

The I-U diagram of the cell according to the invention is shown in FIG. 1. As can be seen from FIG. 1, the switchability of the cell in the presence of air is completely reversible and reproducible.

1.-14. (canceled)

15. A semiconductor having a memory reversibly switchable between different stable electrical resistance states, the memory cell comprising a first electrode and a second electrode and an active layer arranged between the first and the second electrode, the active layer comprising:
a compound represented by general formula 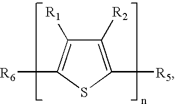
wherein:
R₁ and R₂ are independently selected from the group consisting of —H, —(CH₂)ₘCH₃, -phenyl, —O—(CH₂)ₘCH₃, —O-phenyl, —S(CH₂)ₘCH₃, —S-aryl, —NR₃R₄, —SR₃ and -halogen,
R₁ and R₂ may together form a ring,
R₅ and R₆ are independently selected from —H, -alkyl, -aryl, and -heteroaryl,
m is either 0 or an integer ranging from 1 to 10,
n is an integer ranging from 2 to 1000; and
a compound represented by general formula 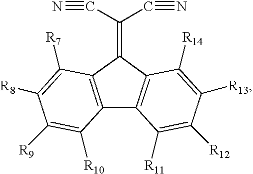
wherein:
R₇, R₈, R₉, R₁₀, R₁₁, R₁₂, R₁₃, and R₁₄ are independently selected from the group consisting of —H, —(CH₂)ₘCH₃, -phenyl, —O—(CH₂)ₘCH₃, —O-phenyl, —CO(CH₂)ₘCH₃, -halogen, —CN and —NO₂,
R₇ and R₈ may together form a ring,
R₈ and R₉ may together form a ring,
R₉ and R₁₀ may together form a ring,
R₁₁ and R₁₂ may together form a ring,
R₁₂ and R₁₃ may together form a ring, and
R₁₃ and R₁₄ may together form a ring.
different

16. The memory of claim 15 wherein the active layer comprises at least two compounds represented by general formula

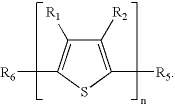

17. The memory of claim 15 wherein the ratio of compounds represented by general represented by general formula 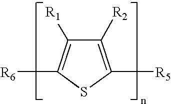
to the compounds of general formula 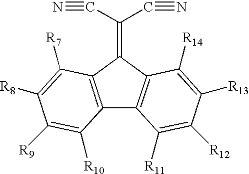
in the active layer is as low as 1:5 to as high as 5:1.

18. The memory of claim 15 wherein R₅ is an alkyl radical with as little as one carbon atom to as many as ten carbon atoms or R₆ is an alkyl radical with as little as one carbon atom to as many as ten carbon atoms.

19. The memory of claim 15 wherein R₅ is an alkyl radical with as little as one carbon atom to as many as ten carbon atoms and R₆ is an alkyl radical with as little as one carbon atom to as many as ten carbon atoms.

20. The memory of claim 15 wherein any -alkyl or -aryl at position R₅ or any -alkyl or -aryl at position R₆ includes a hetero atom.

21. The memory of claim 20 wherein the hetero atom included in any -alkyl or -aryl at position R₅ or the hetero atom included in any -alkyl or -aryl at position R₆ is selected from the group consisting of S, N, and O.

22. The memory of claim 15 wherein the thickness of the active layer is as small as 20 nanometers to as large as 2000 nanometers.

23. The memory of claim 15 wherein the first electrode, the second electrode, or both the first electrode and the second electrode incorporate copper, aluminum, silicon, titanium, tantalum, tungsten, carbon, nitrogen, oxygen, or combinations of these.

24. The memory of claim 23 wherein the first electrode, the second electrode, or both the first electrode and the second electrode comprise aluminum, copper, silicon, titanium, tantalum, tungsten, AlCu, AlSiCu, SiON, SiO, SiN, SiC, SiCN, TiN, TiSiN, TaN, TiW, TaW, WN, WCN, or combinations of these.

25. A semiconductor device comprising at least one memory of claim 15.

26. The semiconductor device of claim 21 wherein the semiconductor element further comprises a substrate in working relation with the first electrode or the second electrode of the memory cell, the substrate comprising silicon, germanium or gallium.

27. A method for manufacturing a semiconductor device having at least one memory cell that is reversibly switchable between different stable electrical resistance states, the method comprising generating a first electrode and a second electrode and depositing an active layer between the first electrode and the second electrode, the active layer comprising:
a compound represented by general formula 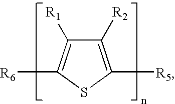
wherein:
R₁ and R₂ are independently selected from the group consisting of —H, —(CH₂)ₘCH₃, -phenyl, —O—(CH₂)ₘCH₃, —O-phenyl, —S(CH₂)ₘCH₃, —S-aryl, —NR₃R₄, —SR₃ and -halogen,
R₁ and R₂ may together form a ring,
R₅ and R₆ are independently selected from —H, -alkyl, -aryl, and -heteroaryl,
m is either 0 or an integer ranging from 1 to 10,
n is an integer ranging from 2 to 1000; and
a compound represented by general formula 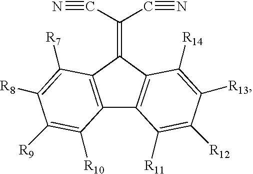
wherein:
R₇, R₈, R₉, R₁₀, R₁₁, R₁₂, R₁₃, and R₁₄ are independently selected from the group consisting of —H, —(CH₂)ₘCH₃, -phenyl, —O—(CH₂)ₘCH₃, —O-phenyl, —CO(CH₂)ₘCH₃, -halogen, —CN and —NO₂,
R₇ and R₈ may together form a ring,
R₈ and R₉ may together form a ring,
R₉ and R₁₀ may together form a ring,
R₁₁ and R₁₂ may together form a ring,
R₁₂ and R₁₃ may together form a ring, and
R₁₃ and R₁₄ may together form a ring.

28. The method of claim 27, the method further comprising incorporating the compound represented by general formula 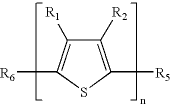
and the compound of general formula 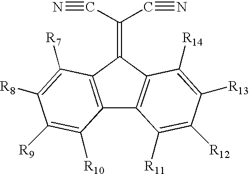
in the active layer via vacuum vapor deposition.

29. The method of claim 27, the method further comprising incorporating the compound represented by general formula 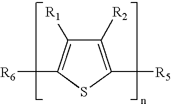
and the compound of general formula 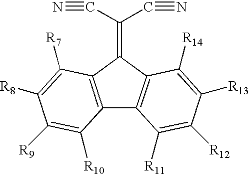
in a solution and spin coating the solution to form the active layer.

30. The method of claim 27 wherein the ratio of compounds represented by general represented by general formula 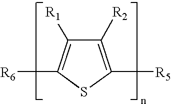
to the compounds of general formula 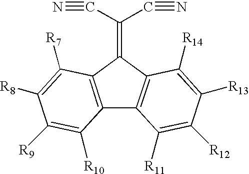
in the active layer is as low as 1:5 to as high as 5:1.

31. The method of claim 27 wherein R₅ is an alkyl radical with as little as one carbon atom to as many as ten carbon atoms or R₆ is an alkyl radical with as little as one carbon atom to as many as ten carbon atoms.

32. The method of claim 27, the method further comprising forming the active layer with a thickness from as small as 20 nanometers to as large as 2000 nanometers.

33. A method of using the memory cell of claim 15, the method comprising incorporating the memory cell in a memory arrangement of semiconductor element that comprises a substrate in working relation with the first electrode or the second electrode of the memory cell.

34. The method of claim 33 wherein the substrate comprises silicon, germanium or gallium.
